(19) United States
(12) Patent Application Publication
(10) Pub. No.: US 2024/0232070 A1
(43) Pub. Date: Jul. 11, 2024

(54) METHOD FOR HANDLING EXTREME TEMPERATURES IN STORAGE DEVICES

(71) Applicant: WESTERN DIGITAL TECHNOLOGIES, INC., San Jose, CA (US)

(72) Inventors: NITIN JAIN, Bangalore (IN); SRIKANTH PEDDAYYAVANDLA, Bangalore (IN)

(73) Assignee: WESTERN DIGITAL TECHNOLOGIES, INC., San Jose, CA (US)

(21) Appl. No.: 18/372,152

(22) Filed: Sep. 25, 2023

Related U.S. Application Data
(60) Provisional application No. 63/479,022, filed on Jan. 9, 2023.

(51) Int. Cl. G06F 12/02

(52) U.S. Cl. CPC G06F 12/0246

(57) ABSTRACT

An AON module on a storage device periodically obtains the temperatures of the storage device and memory device. A controller uses the temperatures obtained by the AON module to determine a calculated temperature. The controller determines when the calculated temperature is above a thermal threshold and causes the storage device to enter the thermal sleep state where normal operations on the storage device are suspended. In the thermal sleep state, power to the AON module is maintained and the power to other components is modified. The AON module starts a cool-off timer and after a cool-off time expires, the AON module causes power to at least one component on the storage device to be turned on to determine whether the temperature of the storage device is below a first thermal throttling threshold and to cause the storage device to resume normal operations.

### CROSS-REFERENCE TO RELATED APPLICATIONS

The present application claims the benefit of U.S. Provisional Application Ser. No. 63/479,022 titled “Notifications for Avoiding Thermal Shutdown,” filed Jan. 9, 2023, which is incorporated by reference herein in its entirety.

### BACKGROUND

Non-volatile storage devices, such as solid-state drives (SSD) and the like, may include one or more memory devices for storing data and a controller for managing the internal operations of the storage device. The controller may monitor the temperatures on the storage device and the memory device to ensure that the thermal states of the storage device and the memory device are in a normal operation zone where the highest performance may be provided as defined in the storage device specification. The controller may also monitor the temperatures on the storage device and the memory device to prevent damage to components on the storage device and the memory device from high temperatures.

When the temperature of the storage device and/or the memory device exceeds one or more operating temperature thresholds, the controller may execute one or more thermal throttling algorithms to bring the temperature into the normal operation zone. For example, when the temperature of the storage device and/or the memory device exceeds a first temperature threshold, the controller may execute one or more thermal throttling algorithms to bring the temperature below the first temperature threshold. If the controller is unsuccessful in reducing the temperature below the first temperature threshold and the temperature rises above a second thermal threshold, the controller may execute one or more thermal throttling algorithms to bring the temperature below the second temperature threshold. If the controller is unsuccessful in reducing the temperature below the second temperature threshold and the temperature rises above a third thermal threshold, the controller may determine that the storage device is in a thermal shutdown zone. In the thermal shutdown zone, the storage device may move to a shutdown state with no active components, wherein, normal operations may be denied to a host which may send instructions to the storage device to read data from and write data to the memory device.

When the storage device is moved to the shutdown state, the host may be unaware of when the storage device may be safely restarted and when normal operations may resume on the storage device. This may prevent the host from using the storage device efficiently and may impact the quality of service provided by the storage device. In a redundant array of independent disks (RAID) or all-flash-array (AFA) system where multiple storage devices may be in a single enclosure, thermal issues arising from high temperatures of components in the enclosure may be prevalent.

In some current implementations, based on the configuration of the storage device and/or the memory device, an estimated cool-off time for allowing the temperatures of the storage device and/or the memory device to return to the normal operation zone may be calculated and provided to the host prior to the storage device entering the thermal shutdown state. When the storage device enters the thermal shutdown state, the host may wait for the cool-off time to expire and may restart the storage device after the cool-off time expires. In some conditions, the cool-off time may be insufficient and the temperatures of the storage device and/or the memory device may not have returned to the normal operation zone after the cool-off time expired. When the host cannot restart the storage device after the cool-off time expires, the host may still be unaware of when the storage device may be safely restarted and when normal operations may resume on the storage device.

### SUMMARY

In some implementations, the storage device resumes normal operations after entering a thermal state during which the normal operations on the storage device are suspended. The storage device includes an always-on (AON) module to periodically obtain the temperatures of the storage device and memory device. The storage device also includes a controller to determine a calculated temperature from the temperatures of the storage device and the memory device, determine that the calculated temperature is above a thermal threshold, and cause the storage device to enter a thermal sleep state. In the thermal sleep state power to the AON module is maintained and the power to other components of the storage device and the memory device is modified to a lower level or completely turned-off. In the thermal sleep state, the AON module starts a cool-off timer and after a cool-off time expires, the AON module causes power to at least one component on the storage device to be turned on to determine whether the temperature of the storage device is below a first thermal throttling threshold and to cause the storage device to resume normal operations.

In some implementations, a method is provided for resuming normal operations on a storage device after entering a thermal state during which the normal operations on the storage device are suspended. The method includes periodically obtaining, by an AON module, the temperatures of the storage device and a memory device. The method also includes determining, by a controller, a calculated temperature from the temperatures of the storage device and the memory device; determining that the calculated temperature is above a thermal threshold; and causing the storage device to enter a thermal sleep state where the power to the AON module is maintained and the power to other components of the storage device and the memory device is modified to a lower level or completely turned-off. The method further includes starting a cool-off timer in the thermal sleep state, by the AON module, and after a cool-off time expires, causing the power to at least one component on the storage device to be turned on to determine whether the temperature of the storage device is below a first thermal throttling threshold and to cause the storage device to resume normal operations.

In some implementations, in the thermal sleep state, the AON module causes power to at least one component on the storage device to be turned on to send an update message to a host device, the update message includes a time remaining before the storage device returns to normal operations.

### BRIEF DESCRIPTION OF THE SEVERAL VIEWS OF THE DRAWINGS

FIG. 1 is a schematic block diagram of an example system in accordance with some implementations.

FIGS. 2A and 2B are flow diagrams of an example process for restoring the storage device to a full performance state after the storage device enters a thermal sleep state where performance on the storage device is suspended in accordance with some implementations.

FIG. 3 is a flow diagram of an example process for alerting a host of the state of a storage device when the storage device is in a thermal sleep state which causes operations on the storage device to cease in accordance with some implementations.

FIG. 4 is a diagram of an example environment in which systems and/or methods described herein are implemented.

FIG. 5 is a diagram of example components of the host of FIG. 1.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of implementations of the present disclosure.

The apparatus and method components have been represented where appropriate by conventional symbols in the drawings, showing those specific details that are pertinent to understanding the implementations of the present disclosure so as not to obscure the disclosure with details that will be readily apparent to those of ordinary skill in the art.

### DETAILED DESCRIPTION OF THE INVENTION

The following detailed description of example implementations refers to the accompanying drawings. The same reference numbers in different drawings may identify the same or similar elements.

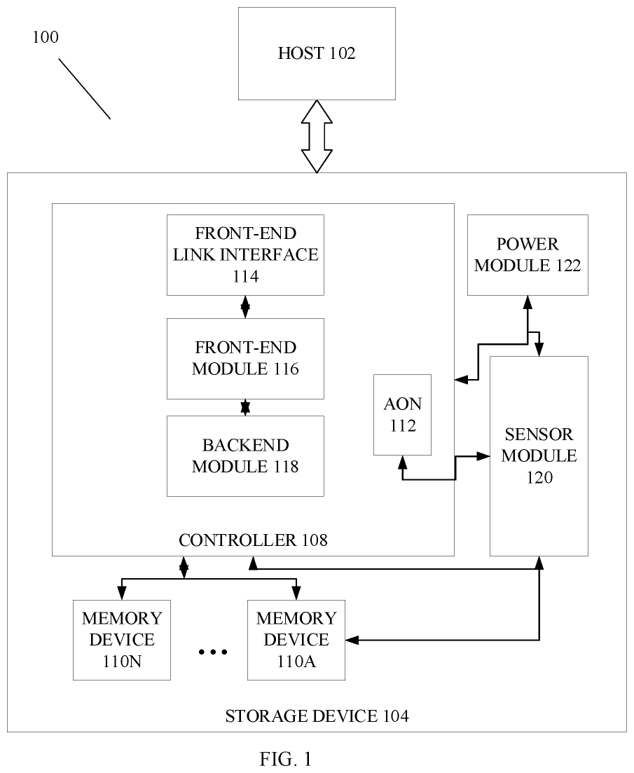

FIG. 1 is a schematic block diagram of an example system in accordance with some implementations. System 100 includes a host 102 and a storage device 104. Host 102 may transmit commands to read or write data to storage device 104. Host 102 and storage device 104 may be in the same physical location as components on a single computing device or on different computing devices that are communicatively coupled. Storage device 104, in various embodiments, may be disposed in one or more different locations relative to the host 102. Host 102 may include additional components (not shown in this figure for the sake of simplicity).

Storage device 104 may include a controller 108 including an always-on (AON) module (112), a front-end link interface 114, a front-end module 116, and a back-end module 118. AON module 112, front-end link interface 114, a front-end module 116, and back-end module 118 may each include a processor to execute internal operations. Storage device 104 may also include one or more memory devices 110a-110n (referred to herein as memory device(s) 110), a sensor module 120, and a power module 122. Storage device 104 may be, for example, a solid-state drive (SSD), and the like. Memory device 110 may be flash based, including, for example, NAND flash memory. Memory device 110 may be included in storage device 104 or may be otherwise communicatively coupled to storage device 104.

Controller 108 may execute background operations to manage resources on memory device 110. Controller 108 may also execute foreground operations to process instructions transmitted from host 102. For example, controller 108 may read data from and/or write data to memory device 110 based on instructions received from host 102. Storage device 104 may interface with host 102 through front-end link interface 114 according to one or more protocols. Storage device 104 may use front-end module 116 to receive and process instructions and data from host 102 and to send responses to host 102. Storage device 104 may interface with memory 110 using back-end module 118. Back-end module 118 may include a flash translation layer and may maintain mapping tables for mapping physical addresses on memory device 110 to logical addresses provided by host 102 for data written to and/or read from memory device 110.

When controller 108 reads from and writes to memory device 110, components on storage device 104 and/or memory device 110 may get heated. Controller 108 may also monitor the temperatures of storage device 104 and memory device 110 to ensure that the thermal states of storage device 104 and memory device 110 are in a normal operation zone. The thermal states of storage device 104 and memory device 110 may be dependent on various components including the thermal levels of multiple integrated circuits on storage device 104 and/or memory device 110, the power consumption on storage device 104 and/or memory device 110, the ambient temperature of storage device 104 and/or memory device 110, and/or user requirements. To protect the thermal states of storage device 104 and memory device 110, sensor module 120 may periodically measure the temperatures of storage device 104 and memory device 110 using thermal detectors placed at multiple places including, for example, inside controller 108, memory device 110, on the printed circuit board, etc. AON 112 may periodically poll sensor module 120 for the temperatures of storage device 104 and memory device 110 as measured using thermal detectors. Controller 108 may make decisions about activities on storage device 104 and/or memory device 110 at predefined polling intervals.

Controller 108 may set thermal throttling thresholds for a calculated temperature determined from the temperatures of storage device 104 and/or memory device 110. For example, controller 108 may determine the calculated temperature to be the highest temperature obtained from storage device 104 and/or memory device 110 during a poll by sensor module 120. Controller 108 may throttle read/write operations on storage device 104 and/or memory device 110 when the calculated temperature reaches thermal throttling thresholds.

In some implementations, controller 108 may throttle read/write operations on storage device 104 and/or memory device 110 in a first throttling zone when the calculated temperature reaches a first thermal throttling threshold. In the first throttling zone, controller 108 may execute read/write operations on storage device 104 and/or memory device 110 such that the performance of storage device 104 may be reduced by a first percentage. For example, in the first throttling zone, storage device 104 and/or memory device 110 may operate at eighty percent of normal operations. If during a subsequent temperature poll controller 108 determines that the calculated temperature did not fall below the first thermal throttling threshold and that the temperature rose to a second thermal throttling threshold, controller 108 may throttle read/write operations on storage device 104 and/or memory device 110 in a second throttling zone. In the second throttling zone, controller 108 may throttle read/write operations on storage device 104 and/or memory device 110 such that the performance of storage device 104 may be reduced by a second percentage for example, performance may be reduced to forty percent of normal operations. Controller 108 may send a warning asynchronous event notification (AEN) message to host 102, notifying host 102 of the thermal state of storage device 104.

If based on a subsequent poll controller 108 determines that the calculated temperature did not fall below the second thermal throttling threshold but instead rose to a thermal threshold, controller 108 may send a critical AEN message to host 102, notifying host 102 of the thermal state of storage device 104. Controller 108 may cause storage device 104 to enter a thermal sleep state. In the thermal sleep state, power to AON 112 may be maintained but power to other components on memory device 110 and storage device 104 may be modified to, for example, a lower level or completely turned-off. For example, components such as front-end link interface 114 and front-end module 116 may be put in the lowest power consumption state and power to components such as back-end module 118 and memory device 110 may be turned off.

Based on the configuration of storage device 104 and/or memory device 110, an estimated cool-off time for allowing the temperatures of storage device 104 and memory device 110 to return to the normal operation zone may be calculated. The cool-off time may be specific to a manufacturer's device/model and the manufacturer may pre-configure firmware in AON 112 to include a single cool-off time or multiple cool-off times based on the internal characteristics of storage device 104 and/or memory device 110. For example, the cool-off time may be a single overall device cool-off time, a storage device cool-off time, a memory device cool-off time, a maximum of the individual cool-off times of storage device 104 and memory device 110, and/or time computed from cool-off time values of one or more internal components of storage device 104.

AON 112 may start a cool-off timer for the preconfigured cool-off time period. When the cool-off time expires, the processor in AON 112 may cause power module 122 to turn on the power to sensor module 120. Sensor module 120 may measure the temperatures of storage device 104 and memory device 110 using thermal detectors placed at various points in storage device 104 and memory device 110. AON 112 may poll sensor module 120 for the temperatures of storage device 104 and memory device 110. If the temperatures of storage device 104 and memory device 110 are below the first thermal throttling threshold, AON 112 may cause power module 122 to turn on the power to other components of storage device 104 and memory device 110, restoring storage device 104 and memory device 110 to a full performance state. AON 112 may send a drive-ready AEN message to host 102 to inform host 102 that storage device 104 is operational.

If, after the cool-off time the temperature of storage device 104 or memory device 110 is above the first thermal throttling threshold, AON 112 may restart the cool-off timer for a preconfigured cool-off time period. When the restarted cool-off time period expires, AON 112 may obtain the temperatures of storage device 104 and memory device 110, compare the temperatures of storage device 104 and memory device 110 to the first thermal throttling threshold, and cause the restoration of storage device 104 to full performance if the temperatures are below the first thermal throttling threshold. Storage device 104 may thus be automatically restored to full performance after being in the thermal sleep state without intervention from host 102.

In some implementations, during the thermal sleep state, AON 112 may cause front-end link interface 114 and front-end module 116 to periodically return to an active power mode for one or more short periods of time. During these periods, AON 112 may send an update AEN message to host 102. The update AEN message may include the time remaining before storage device 104 may resume normal operations and return to full performance. These periodic updates may assist host 102 in determining the current state of storage device 104 and enable host 102 to plan for future operations/workloads on storage device 104. AON 112 may cause front-end link interface 114 and front-end module 116 to return to low power mode after sending the update AEN message to host 102. This enables the host-storage device interface to remain up during high thermal situations. By not requiring intervention from host 102 to automatically restore storage device 104 to full performance after a thermal state and by notifying host 102 of when storage device 104 may exit from the thermal sleep state, the quality of service for redundant array of independent disks (RAID) or all-flash-array (AFA) users may be improved.

Storage device 104 may perform these processes based on a processor, for example, controller 108 and/or AON 112 executing software instructions stored by a non-transitory computer-readable medium, such as storage component 110. As used herein, the term “computer-readable medium” refers to a non-transitory memory device. Software instructions may be read into storage component 110 from another computer-readable medium or from another device. When executed, software instructions stored in storage component 110 may cause controller 108 and/or AON 112 to perform one or more processes described herein. Additionally, or alternatively, hardware circuitry may be used in place of or in combination with software instructions to perform one or more processes described herein. Thus, implementations described herein are not limited to any specific combination of hardware circuitry and software. System 100 may include additional components (not shown in this figure for the sake of simplicity). FIG. 1 is provided as an example. Other examples may differ from what is described in FIG. 1.

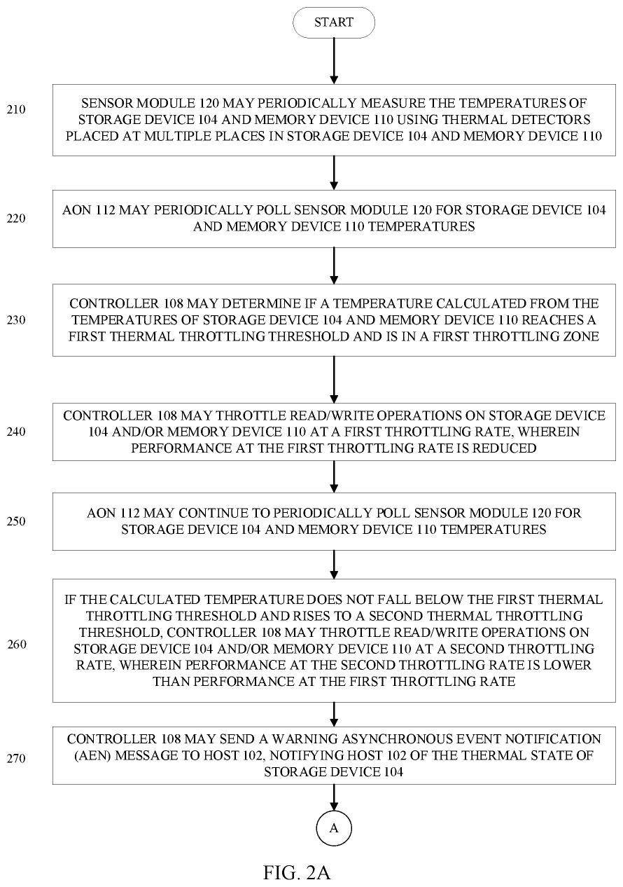

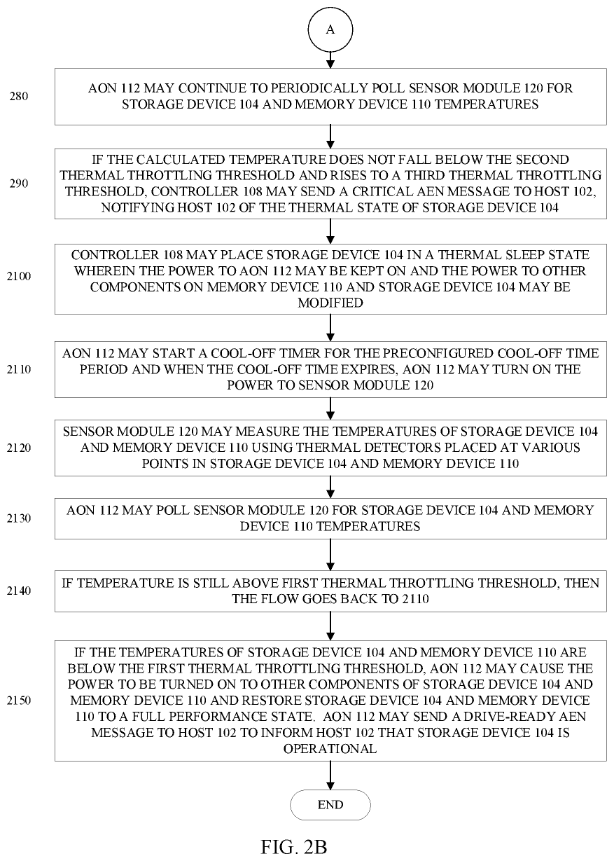

FIGS. 2A and 2B are flow diagrams of an example process for restoring the storage device to a full performance state after the storage device enters a thermal sleep state where performance on the storage device is suspended in accordance with some implementations. At 210, sensor module 120 may periodically measure the temperatures of storage device 104 and memory device 110 using thermal detectors placed at multiple places in storage device 104 and memory device 110. At 220, AON 112 may periodically poll sensor module 120 for storage device 104 and memory device 110 temperatures. At 230, controller 108 may determine if a temperature calculated from the temperatures of storage device 104 and memory device 110 reaches a first thermal throttling threshold and is in a first throttling zone. At 240, controller 108 may throttle read/write operations on storage device 104 and/or memory device 110 at a first throttling rate, wherein performance at the first throttling rate is reduced. At 250, AON 112 may continue to periodically poll sensor module 120 for storage device 104 and memory device 110 temperatures. At 260, if the calculated temperature does not fall below the first thermal throttling threshold and rises to a second thermal throttling threshold, controller 108 may throttle read/write operations on storage device 104 and/or memory device 110 at a second throttling rate, wherein performance at the second throttling rate is lower than performance at the first throttling rate. At 270, controller 108 may send a warning asynchronous event notification (AEN) message to host 102, notifying host 102 of the thermal state of storage device 104.

At 280, AON 112 may continue to periodically poll sensor module 120 for storage device 104 and memory device 110 temperatures. At 290, if the calculated temperature does not fall below the second thermal throttling threshold and rises to a third thermal throttling threshold, controller 108 may send a critical AEN message to host 102, notifying host 102 of the thermal state of storage device 104. At 2100, controller 108 may place storage device 104 in a thermal sleep state wherein the power to AON 112 may be kept on and the power to other components on memory device 110 and storage device 104 may be modified.

At 2110, AON 112 may start a cool-off timer for the preconfigured cool-off time period and when the cool-off time expires, AON 112 may turn on the power to sensor module 120. At 2120, sensor module 120 may measure the temperatures of storage device 104 and memory device 110 using thermal detectors placed at various points in storage device 104 and memory device 110. At 2130, AON 112 may poll sensor module 120 for storage device 104 and memory device 110 temperatures. At 2140, if the temperatures of storage device 104 and memory device 110 are below the first thermal throttling threshold, AON 112 may cause the power to be turned on to other components of storage device 104 and memory device 110 and restore storage device 104 and memory device 110 to a full performance state. AON 112 may send a drive-ready AEN message to host 102 to inform host 102 that storage device 104 is operational. As indicated above FIG. 2 is provided as an example. Other examples may differ from what is described in FIG. 2.

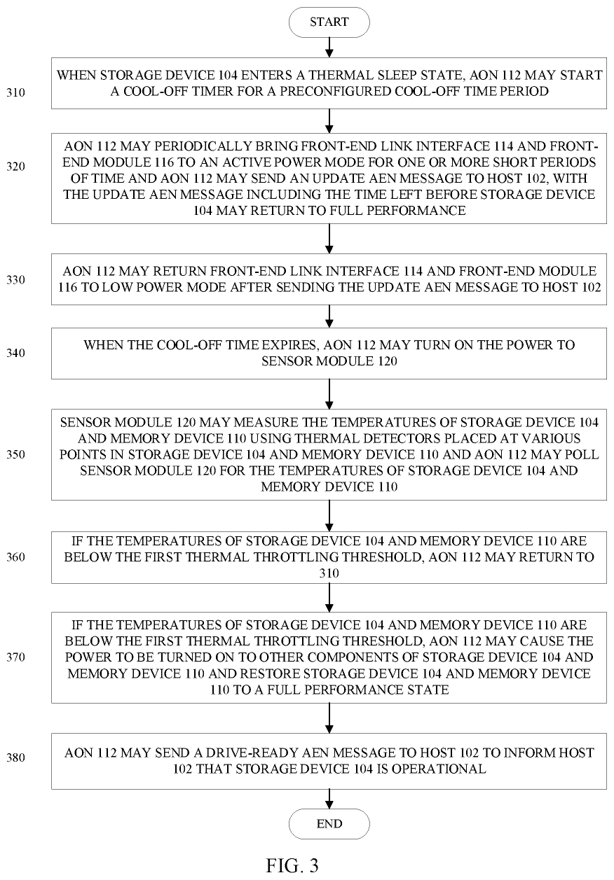

FIG. 3 is a flow diagram of an example process for alerting a host of the state of a storage device when the storage device is in a thermal sleep state which causes operations on the storage device to cease in accordance with some implementations. At 310, when storage device 104 enters a thermal sleep state, AON 112 may start a cool-off timer for a preconfigured cool-off time period. At 320, AON 112 may periodically bring front-end link interface 114 and front-end module 116 to an active power mode for one or more short periods of time and AON 112 may send an update AEN message to host 102, with the update AEN message including the time left before storage device 104 may return to full performance. At 330, AON 112 may return front-end link interface 114 and front-end module 116 to low power mode after sending the update AEN message to host 102. At 340, when the cool-off time expires, AON 112 may turn on the power to sensor module 120. At 350, sensor module 120 may measure the temperatures of storage device 104 and memory device 110 using thermal detectors placed at various points in storage device 104 and memory device 110 and AON 112 may poll sensor module 120 for the temperatures of storage device 104 and memory device 110. At 360, if the temperatures of storage device 104 and memory device 110 are below the first thermal throttling threshold, AON 112 may cause the power to be turned on to other components of storage device 104 and memory device 110 and restore storage device 104 and memory device 110 to a full performance state. At 370, AON 112 may send a drive-ready AEN message to host 102 to inform host 102 that storage device 104 is operational. As indicated above FIG. 3 is provided as an example. Other examples may differ from what is described in FIG. 3.

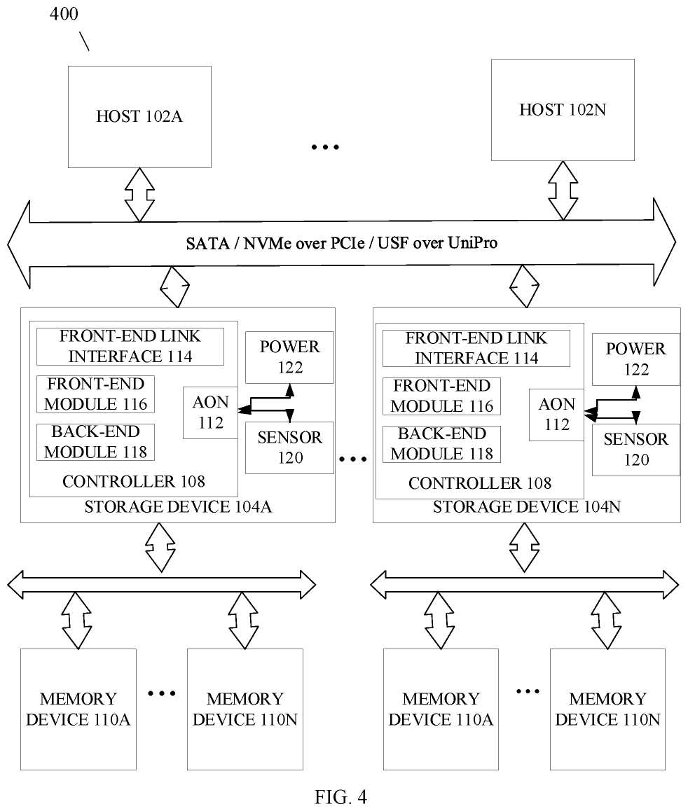

FIG. 4 is a diagram of an example environment in which systems and/or methods described herein are implemented. As shown in FIG. 4, Environment 400 may include hosts 102-102n (referred to herein as host(s) 102), and storage devices 104a-104n (referred to herein as storage device(s) 104).

Storage device 104 may include a controller 108 to manage the resources on storage device 104. AON 112 in controller 108 may monitor the temperatures of storage device 104 and memory device 110. Controller 108 may place storage device 104 in a thermal sleep state when the temperatures of storage device 104 and memory device 110 exceed a given threshold. When in the thermal sleep state, AON may monitor the temperatures of storage device 104 and memory device 110 after a cool-off timer expires and may cause storage device 104 to be restarted when the temperatures of storage device 104 and memory device 110 fall below a given temperature threshold. Hosts 102 and storage devices 104 may communicate via a Serial AT attachment (SATA) interface, Non-Volatile Memory Express (NVMe) over peripheral component interconnect express (PCI Express or PCIe) interface, the Universal Flash Storage (UFS) over Unipro, or the like.

Devices of Environment 400 may interconnect via wired connections, wireless connections, or a combination of wired and wireless connections. For example, the network of FIG. 4 may include a cellular network (e.g., a long-term evolution (LTE) network, a code division multiple access (CDMA) network, a 3G network, a 4G network, a 5G network, another type of next-generation network, and/or the like), a public land mobile network (PLMN), a local area network (LAN), a wide area network (WAN), a metropolitan area network (MAN), a telephone network (e.g., the Public Switched Telephone Network (PSTN)), a private network, an ad hoc network, an intranet, the Internet, a fiber optic-based network, a cloud computing network, or the like, and/or a combination of these or other types of networks.

The number and arrangement of devices and networks shown in FIG. 4 are provided as an example. In practice, there may be additional devices and/or networks, fewer devices and/or networks, different devices and/or networks, or differently arranged devices and/or networks than those shown in FIG. 4. Furthermore, two or more devices shown in FIG. 4 may be implemented within a single device, or a single device shown in FIG. 4 may be implemented as multiple, distributed devices. Additionally, or alternatively, a set of devices (e.g., one or more devices) of Environment 400 may perform one or more functions described as being performed by another set of devices of Environment 400.

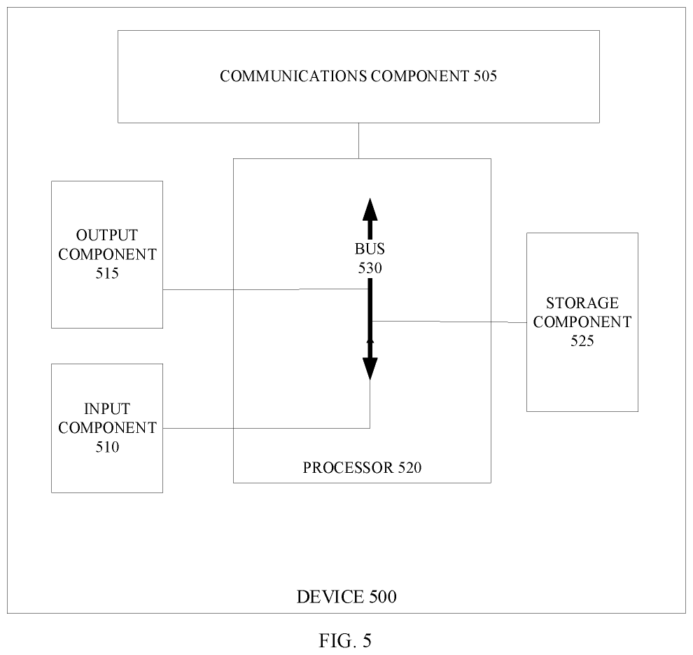

FIG. 5 is a diagram of example components of one or more devices of FIG. 1. In some implementations, host 102 may include one or more devices 500 and/or one or more components of device 500. Device 500 may include, for example, a communications component 505, an input component 510, an output component 515, a processor 520, a storage component 525, and a bus 530. Bus 530 may include components that enable communication among multiple components of device 500, wherein components of device 500 may be coupled to be in communication with other components of device 500 via bus 530.

Input component 510 may include components that permit device 500 to receive information via user input (e.g., keypad, a keyboard, a mouse, a pointing device, a microphone, and/or a display screen), and/or components that permit device 500 to determine the location or other sensor information (e.g., an accelerometer, a gyroscope, an actuator, another type of positional or environmental sensor). Output component 515 may include components that provide output information from device 500 (e.g., a speaker, display screen, and/or the like). Input component 510 and output component 515 may also be coupled to be in communication with processor 520.

Processor 520 may be a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some implementations, processor 520 may include one or more processors capable of being programmed to perform a function. Processor 520 may be implemented in hardware, firmware, and/or a combination of hardware and software.

Storage component 525 may include one or more memory devices, such as random-access memory (RAM) 114, read-only memory (ROM), and/or another type of dynamic or static storage device (e.g., a flash memory, a magnetic memory, and/or optical memory) that stores information and/or instructions for use by processor 520. A memory device may include memory space within a single physical storage device or memory space spread across multiple physical storage devices. Storage component 525 may also store information and/or software related to the operation and use of device 500. For example, storage component 525 may include a hard disk (e.g., a magnetic disk, an optical disk, and/or a magneto-optic disk), a solid-state drive (SSD), a compact disc (CD), a digital versatile disc (DVD), a floppy disk, a cartridge, a magnetic tape, and/or another type of non-transitory computer-readable medium, along with a corresponding drive.

Communications component 505 may include a transceiver-like component that enables device 500 to communicate with other devices, such as via a wired connection, a wireless connection, or a combination of wired and wireless connections. The communications component 505 may permit device 500 to receive information from another device and/or provide information to another device. For example, communications component 505 may include an Ethernet interface, an optical interface, a coaxial interface, an infrared interface, a radio frequency (RF) interface, a universal serial bus (USB) interface, a Wi-Fi interface, and/or a cellular network interface that may be configurable to communicate with network components, and other user equipment within its communication range.

Communications component 505 may also include one or more broadband and/or narrowband transceivers and/or other similar types of wireless transceiver configurable to communicate via a wireless network for infrastructure communications. Communications component 505 may also include one or more local area network or personal area network transceivers, such as a Wi-Fi transceiver or a Bluetooth transceiver.

Device 500 may perform one or more processes described herein. For example, device 500 may perform these processes based on processor 520 executing software instructions stored by a non-transitory computer-readable medium, such as storage component 525. As used herein, the term “computer-readable medium” refers to a non-transitory memory device. Software instructions may be read into storage component 525 from another computer-readable medium or from another device via communications component 505. When executed, software instructions stored in storage component 525 may cause processor 520 to perform one or more processes described herein. Additionally, or alternatively, hardware circuitry may be used in place of or in combination with software instructions to perform one or more processes described herein. Thus, implementations described herein are not limited to any specific combination of hardware circuitry and software.

The number and arrangement of components shown in FIG. 5 are provided as an example. In practice, device 500 may include additional components, fewer components, different components, or differently arranged components than those shown in FIG. 5. Additionally, or alternatively, a set of components (e.g., one or more components) of device 500 may perform one or more functions described as being performed by another set of components of device 500.

The foregoing disclosure provides illustrative and descriptive implementations but is not intended to be exhaustive or to limit the implementations to the precise form disclosed herein. One of ordinary skill in the art will appreciate that various modifications and changes can be made without departing from the scope of the present disclosure as set forth in the claims below. Accordingly, the specification and figures are to be regarded in an illustrative rather than a restrictive sense, and all such modifications are intended to be included within the scope of present teachings.

As used herein, the term “component” is intended to be broadly construed as hardware, firmware, and/or a combination of hardware and software. It will be apparent that systems and/or methods described herein may be implemented in different forms of hardware, firmware, and/or a combination of hardware and software.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set.

No element, act, or instruction used herein should be construed as critical or essential unless explicitly described as such. Also, as used herein, the articles “a” and “an” are intended to include one or more items and may be used interchangeably with “one or more.” Furthermore, as used herein, the term “set” is intended to include one or more items (e.g., related items, unrelated items, a combination of related items, unrelated items, and/or the like), and may be used interchangeably with “one or more” The term “only one” or similar language is used where only one item is intended. Further, the phrase “based on” is intended to mean “based, at least in part, on” unless explicitly stated otherwise.

Moreover, in this document, relational terms such as first and second, top and bottom, and the like, may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, or “contains . . . a” does not, without more constraints, preclude the existence of additional identical elements in the process, method, article, or apparatus that comprises, has, includes, contains the element. The terms “substantially”, “essentially”, “approximately”, “about” or any other version thereof, are defined as being close to as understood by one of ordinary skill in the art, and in one non-limiting implementation, the term is defined to be within 10%, in another implementation within 5%, in another implementation within 1% and in another implementation within 0.5%. The term “coupled” as used herein is defined as connected, although not necessarily directly and not necessarily mechanically. A device or structure that is “configured” in a certain way is configured in at least that way but may also be configured in ways that are not listed.

We claim:

1. A storage device to resume full performance after the storage device enters a thermal sleep state where performance on the storage device is suspended, the storage device comprising:
an always-on (AON) module to periodically obtain temperatures of the storage device and a memory device; and
a controller to determine a calculated temperature from the temperatures of the storage device and the memory device, determine that the calculated temperature is above a thermal threshold, and cause the storage device to enter a thermal sleep state where power to the AON module is maintained and the power to other components of the storage device and the memory device is modified,
wherein in the thermal sleep state the AON module starts a cool-off timer and after a cool-off time expires, the AON module causes power to at least one component on the storage device to be turned on to determine whether the temperature of the storage device is below a first thermal throttling threshold and to cause the storage device to resume normal operations.

2. The storage device of claim 1, wherein the AON module sends a drive-ready asynchronous event notification (AEN) message to a host device when the storage device resumes normal operations.

3. The storage device of claim 1, wherein when the cool-off time expires, the AON module causes power to a sensor module to turn on to obtain the temperatures of the storage device and the memory device.

4. The storage device of claim 1, wherein when the cool-off time expires, if the temperature of the storage device is above the first thermal throttling threshold the AON module restarts the cool-off timer.

5. The storage device of claim 1, wherein in the thermal sleep state, the power to other components of the storage device and the memory device is one of turned off and put in a lowest power consumption state.

6. The storage device of claim 1, wherein during the thermal sleep state, the AON module causes at least one component of the storage device to return to an active power mode for a period of time, and the AON module sends a message to a host device during the period of time, updating the host device on time left before the storage device resumes normal operations.

7. The storage device of claim 1, wherein the calculated temperature is determined to be the highest temperature obtained from the storage device and the memory device.

8. The storage device of claim 1, wherein the controller sets thermal throttling thresholds including the first thermal throttling threshold, a second thermal throttling threshold, and the thermal threshold, wherein when the calculated temperature reaches the first thermal throttling threshold, performance of the storage device is reduced by a first percentage, when the calculated temperature reaches the second thermal throttling threshold, the performance of the storage device is reduced by a second percentage, and when the calculated temperature reaches the thermal threshold, the storage device is placed in the thermal sleep state.

9. The storage device of claim 8 wherein when the calculated temperature reaches the second thermal throttling threshold, the controller sends a warning AEN message to a host device, notifying the host device of the thermal state of the storage device.

10. The storage device of claim 8 wherein when the calculated temperature reaches the thermal threshold, the controller sends a critical AEN message to a host device, notifying the host device of the thermal state of the storage device.

11. A method for resuming normal operations on a storage device after entering a thermal state during which the normal operations on the storage device are suspended, the method comprises:
periodically obtaining, by an AON module, temperatures of the storage device and a memory device;
determining, by a controller, a calculated temperature from the temperatures of the storage device and the memory device;
determining, by the controller, that the calculated temperature is above a thermal threshold;
causing, by the controller, the storage device to enter a thermal sleep state where power to the AON module is maintained and the power to other components of the storage device and the memory device is modified,
starting, by the AON module, a cool-off timer in the thermal sleep state;
after a cool-off time expires, causing, by the AON module, power to at least one component on the storage device to be turned on to determine whether the temperature of the storage device is below a first thermal throttling threshold and to cause the storage device to resume normal operations.

12. The method of claim 11, further comprising sending, by the controller, a drive-ready asynchronous event notification (AEN) message to a host device when the storage device resumes normal operations.

13. The method of claim 11, wherein when the cool-off time expires, causing, by the AON module, power to a sensor module to turn on to obtain the temperatures of the storage device and the memory device.

14. The method of claim 11, further comprising restarting, by the AON module, the cool-off timer if the temperature of the storage device is above the first thermal throttling threshold.

15. The method of claim 11, further comprising, in the thermal sleep state, one of turning off the power and turning on a lowest power consumption state for other components of the storage device and the memory device, by the controller.

16. The method of claim 11, further comprising in the thermal sleep state, causing, by the AON module, at least one component of the storage device to return to an active power mode for a period of time, and sending, by the AON module, a message to a host device during the period of time, the message updating the host device on time left before the storage device resumes normal operations.

17. The method of claim 11, further comprising setting, by the controller, thermal throttling thresholds including the first thermal throttling threshold, a second thermal throttling threshold, and the thermal threshold, wherein when the calculated temperature reaches the first thermal throttling threshold, performance of the storage device is reduced by a first percentage, when the calculated temperature reaches the second thermal throttling threshold, the performance of the storage device is reduced by a second percentage, and when the calculated temperature reaches the thermal threshold, the storage device is placed in the thermal sleep state.

18. The method of claim 17, further comprising:
when the calculated temperature reaches the second thermal throttling threshold, sending, by the controller, a warning AEN message to a host device, notifying the host device of the thermal state of the storage device; and
when the calculated temperature reaches the thermal threshold, sending, by the controller, a critical AEN message to the host device, notifying the host device of the thermal state of the storage device.

19. A storage device to resume normal operations after entering a thermal state during which the normal operations on the storage device are suspended, the storage device comprising:
an always-on (AON) module to periodically obtain temperatures of the storage device and a memory device; and
a controller to determine a calculated temperature from the temperatures of the storage device and the memory device, determine that the calculated temperature is above a thermal threshold, and cause the storage device to enter a thermal sleep state where power to the AON module is maintained and the power to other components of the storage device and the memory device is modified,
wherein in the thermal sleep state the AON module starts a cool-off timer and after a cool-off time expires, the AON module causes power to at least one component on the storage device to be turned on to determine whether the temperature of the storage device is below a first thermal throttling threshold and to cause the storage device to resume normal operations; and
wherein in the thermal sleep state the AON module causes power to at least one component on the storage device to periodically be turned on to send an update message to a host device, the update message including a time remaining before the storage device returns to normal operations.
